(19) United States
(12) Patent Application Publication
(10) Pub. No.: US 2025/0343198 A1
(43) Pub. Date: Nov. 6, 2025

(54) SEMICONDUCTOR DEVICE HAVING A WIRING MEMBER WITH AN UNEVEN BONDING SURFACE

(71) Applicant: FUJI ELECTRIC CO., LTD., Kawasaki-shi (JP)

(72) Inventors: Yoko NAKAMURA, Matsumoto-city (JP); Takafumi YAMADA, Matsumoto-city (JP); Yuta TAMAI, Matsumoto-city (JP); Akihiko IWAYA, Tokyo (JP); Eiji IMAI, Matsumoto-city (JP); Daisuke INOUE, Matsumoto-city (JP); Yuya ISHIKURA, Matsumoto-city (JP); Daiki YOSHIDA, Matsumoto-city (JP)

(73) Assignee: FUJI ELECTRIC CO., LTD., Kawasaki-shi (JP)

(21) Appl. No.: 19/062,701

(22) Filed: Feb. 25, 2025

(30) Foreign Application Priority Data
May 2, 2024 (JP) 2024-074625

(51) Int. Cl. H01L 23/00

(52) U.S. Cl. CPC H01L 24/37; H01L 24/40; H01L 2224/37005; H01L 2224/37013; H01L 2224/37111; H01L 2224/3712; H01L 2224/37147; H01L 2224/404

(57) ABSTRACT

A semiconductor device, including: a semiconductor chip having a first electrode and a second electrode respectively on a upper surface and a lower surface thereof; and a wiring member including a bonding portion having a bonding surface, which is bonded to the first electrode with a solder therebetween, and a rising portion extending from an outer periphery of the bonding portion, the bonding surface being located, in a plan view of the semiconductor device, within the upper surface of the semiconductor chip. The bonding surface has an outer edge area and a middle area. In a height direction of the semiconductor device, a first height from the outer edge area of the bonding surface to the upper surface of the semiconductor chip is greater than a second height from the middle area of the bonding surface to the upper surface of the semiconductor chip.

### CROSS-REFERENCE TO RELATED APPLICATION

This application is based upon and claims the benefit of priority of the prior Japanese Patent Application No. 2024-074625, filed on May 2, 2024, the entire contents of which are incorporated herein by reference.

### BACKGROUND OF THE INVENTION

### 1. Field of the Invention

The embodiments discussed herein relate to a semiconductor device having a wiring member with an uneven bonding surface.

### 2. Background of the Related Art

Semiconductor devices include a conductive plate, a semiconductor chip bonded to the conductive plate with solder, and a lead frame bonded with solder to an electrode on an upper surface of the semiconductor chip (see, for example, literatures (1) to (6)).
(1) Japanese Laid-open Patent Publication No. 2017-079228
(2) Japanese Laid-open Patent Publication No. 2015-128194
(3) International Publication Pamphlet No. WO 2020/003495
(4) International Publication Pamphlet No. WO 2019/167102
(5) Japanese Laid-open Patent Publication No. 2013-004943
(6) International Publication Pamphlet No. WO 2023/119837

### SUMMARY OF THE INVENTION

According to an aspect, there is provided a semiconductor device, including: a semiconductor chip including a first electrode on an upper surface thereof and a second electrode on a lower surface thereof; and a wiring member including a bonding portion having a bonding surface, which is bonded to the first electrode with a solder therebetween, and a rising portion extending from an outer periphery of the bonding portion, the bonding surface being located, in a plan view of the semiconductor device, within the upper surface of the semiconductor chip, wherein the bonding surface has an outer edge area and a middle area different from the outer edge area, and in a height direction of the semiconductor device, a first height from the outer edge area of the bonding surface to the upper surface of the semiconductor chip is greater than a second height from the middle area of the bonding surface to the upper surface of the semiconductor chip.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a plan view of a semiconductor unit included in the semiconductor device according to the first embodiment;

FIG. 4 is a side sectional view of the semiconductor unit included in the semiconductor device according to the first embodiment (part 1);

FIG. 5 is an enlarged side sectional view of the semiconductor unit included in the semiconductor device according to the first embodiment;

FIG. 6 is a side sectional view of the semiconductor unit included in the semiconductor device according to the first embodiment (part 2);

FIG. 7 is a side sectional view of a semiconductor unit included in a semiconductor device taken as reference example 1;

FIG. 8 is a plan view of the semiconductor unit included in the semiconductor device taken as reference example 1;

FIG. 9 is a side sectional view of a semiconductor unit included in a semiconductor device taken as reference example 2;

FIG. 10 is a plan view of a semiconductor unit included in a semiconductor device according to the first embodiment (modification 1-1);

FIG. 11 is a plan view of a semiconductor unit included in a semiconductor device according to the first embodiment (modification 1-2);

FIG. 12 is an enlarged side sectional view of a semiconductor unit included in a semiconductor device according to a second embodiment;

FIG. 13 is a side sectional view of the semiconductor unit included in the semiconductor device according to the second embodiment; and

FIG. 14 is an enlarged side sectional view of a semiconductor unit included in a semiconductor device according to a third embodiment.

### DETAILED DESCRIPTION OF THE INVENTION

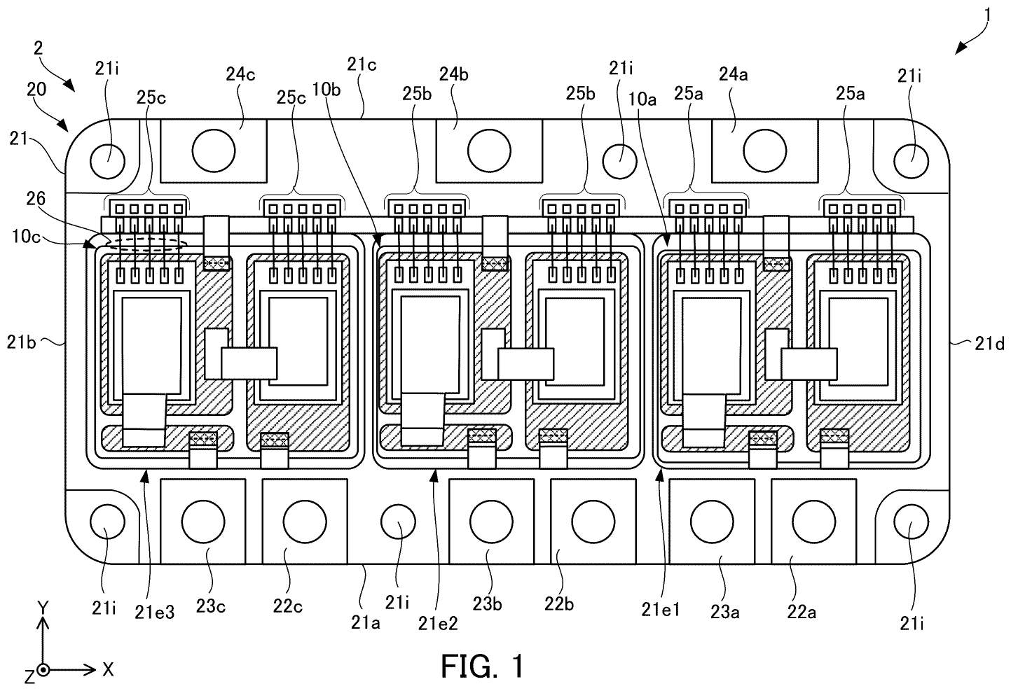

Embodiments will now be described with reference to the accompanying drawings. In the following description, a “front surface” and an “upper surface” indicate an X-Y plane which faces the upper side (+Z direction) in a semiconductor device 1 of FIG. 1. Similarly, an “upside” indicates the upward direction (+Z direction) in the semiconductor device 1 of FIG. 1. A “back surface” and a “lower surface” indicate the X-Y plane which faces the lower side (−Z direction) in the semiconductor device 1 of FIG. 1.

Similarly, a “downside” indicates the downward direction (−Z direction) in the semiconductor device 1 of FIG. 1. These terms mean the same directions at need in the other drawings. “Highly placed” and “placed above” indicate an upward position (+Z direction) in the semiconductor device 1 of FIG. 1. Similarly, “placed low” and “placed below” indicate a downward position (−Z direction) in the semiconductor device 1 of FIG. 1. The “front surface,” the “upper surface,” the “upside,” the “back surface,” the “lower surface,” the “downside,” and a “side” are simply used as expedient representation for specifying relative positional relationships and do not limit the technical idea of the present disclosure. For example, the “upside” and the “downside” do not always mean the vertical direction relative to the ground. That is to say, a direction indicated by the “upside” and the “downside” is not limited to the gravity direction. Furthermore, in the following description, a “main component” indicates a component contained at a rate of 80 volume percent (vol %) or more. In addition, “approximately equal” means that two objects are in the range of +10%. Moreover, “perpendicular”, “rectangular,” and “parallel” mean that an angle which one object forms with the other object is in the range of 90°±10° or 180°±10°.

### First Embodiment

A semiconductor device 1 according to a first embodiment will be described with reference to FIG. 1 and

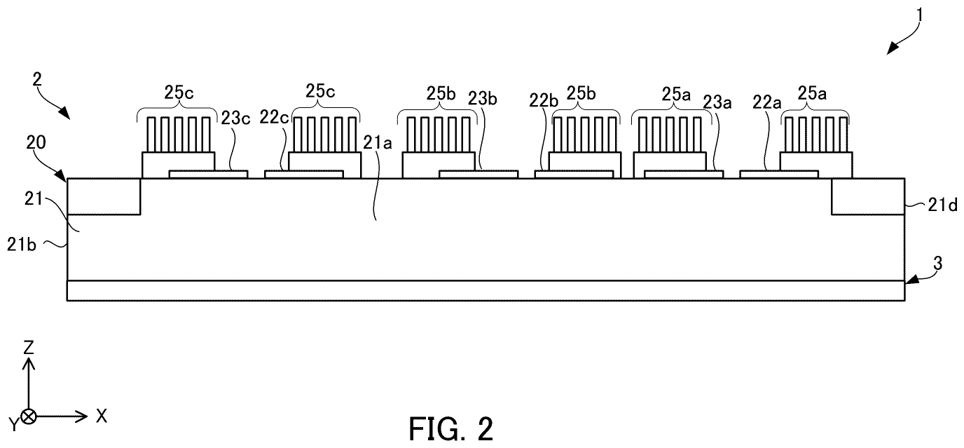

FIG. 2. FIG. 1 is a plan view of a semiconductor device according to the first embodiment. FIG. 2 is a side view of the semiconductor device according to the first embodiment. FIG. 2 is a side view obtained by viewing a side part parallel to an X-Z plane of the semiconductor device 1 of FIG. 1 from the +Y direction.

The semiconductor device 1 includes a semiconductor module 2 and a heat dissipation plate 3. Furthermore, the semiconductor module 2 includes semiconductor units 10a, 10b, and 10c and a case 20 which houses the semiconductor units 10a, 10b, and 10c. The semiconductor units 10a, 10b, and 10c housed in the case 20 are sealed with a sealing member (not illustrated). The semiconductor units 10a, 10b, and 10c have the same structure. If no distinctions are made among the semiconductor units 10a, 10b, and 10c, then description will be given as the semiconductor units 10. The details of the semiconductor units 10 will be described later.

The case 20 included in the semiconductor module 2 includes an outer frame 21, first connection terminals 22a, 22b, and 22c, second connection terminals 23a, 23b, and 23c, a W-phase output terminal 24a, a V-phase output terminal 24b, a U-phase output terminal 24c, and control terminals 25a, 25b, and 25c.

The outer frame 21 is approximately rectangular in plan view and is surrounded on all sides by outer walls 21a, 21b, 21c, and 21d. The outer walls 21a and 21c correspond to long sides of the outer frame 21 and the outer walls 21b and 21d correspond to short sides of the outer frame 21. Furthermore, each of corner portions at which the outer walls 21a, 21b, 21c, and 21d are connected to one another does not always have a right angle. As illustrated in FIG. 1, each corner portion may be R-chamfered. Fastening holes 21i which pierce the outer frame 21 are made in the corner portions of the front surface of the outer frame 21. The fastening holes 21i may be made in the corner portions of the outer frame 21 below the front surface of the outer frame 21.

Unit housing portions 21e1, 21e2, and 21e3 are formed in the front surface of the outer frame 21 along the outer walls 21a and 21c. The unit housing portions 21e1, 21e2, and 21e3 are rectangular in plan view. The semiconductor units 10a, 10b, and 10c are housed in the unit housing portions 21e1, 21e2, and 21e3, respectively. As described later, the semiconductor units 10a, 10b, and 10c are arranged in the X direction over the front surface of the heat dissipation plate 3. The outer frame 21 is fixed to the front surface of the heat dissipation plate 3 and the semiconductor units 10a, 10b, and 10c are surrounded by (housed in) the unit housing portions 21e1, 21e2, and 21e3, respectively, of the outer frame 21.

In plan view, the outer frame 21 has the first connection terminals 22a, 22b, and 22c and the second connection terminals 23a, 23b, and 23c on the front surface on the side of the outer wall 21a. The first connection terminals 22a, 22b, and 22c and the second connection terminals 23a, 23b, and 23c correspond to the unit housing portions 21e1, 21e2, and 21e3, respectively. One end portions of the first connection terminals 22a, 22b, and 22c and the second connection terminals 23a, 23b, and 23c are exposed on the front surface on the side of the outer wall 21a. The other end portions of the first connection terminals 22a, 22b, and 22c and the second connection terminals 23a, 23b, and 23c are exposed in the unit housing portions 21e1, 21e2, and 21e3 and are electrically connected to the semiconductor units 10a, 10b, and 10c.

In the unit housing portion 21e2, for example, the other end portions of the first connection terminal 22b and the second connection terminal 23b are bonded to the semiconductor unit 10b (to conductive circuit patterns 11b1 and 11b3, respectively, included in the semiconductor unit 10b and described later). Similarly, the other end portions of the first connection terminal 22a and the second connection terminal 23a are bonded to the semiconductor unit 10a (to conductive circuit patterns 11b1 and 11b3, respectively, included in the semiconductor unit 10a and described later). Furthermore, the other end portions of the first connection terminal 22c and the second connection terminal 23c are bonded to the semiconductor unit 10c (to conductive circuit patterns 11b1 and 11b3, respectively, included in the semiconductor unit 10c and described later).

In addition, the outer frame 21 has the W-phase output terminal 24a, the V-phase output terminal 24b, and the U-phase output terminal 24c on the front surface on the side of the outer wall 21c. The W-phase output terminal 24a, the V-phase output terminal 24b, and the U-phase output terminal 24c correspond to the unit housing portions 21el, 21e2, and 21e3, respectively. One end portions of the W-phase output terminal 24a, the V-phase output terminal 24b, and the U-phase output terminal 24c are exposed on the front surface on the side of the outer wall 21c. The other end portions of the W-phase output terminal 24a, the V-phase output terminal 24b, and the U-phase output terminal 24c are exposed in the unit housing portions 21e1, 21e2, and 21e3, respectively, and are electrically connected to the semiconductor units 10a, 10b, and 10c, respectively.

In the unit housing portion 21e2, for example, the other end portion of the V-phase output terminal 24b is bonded to the semiconductor unit 10b (to a conductive circuit pattern 11b2 included in the semiconductor unit 10b and described later) by ultrasonic bonding. Similarly, the other end portions of the W-phase output terminal 24a and the U-phase output terminal 24c are bonded to the 10c, respectively, (to semiconductor units 10a and conductive circuit patterns 11b2 included in the semiconductor units 10a and 10c, respectively, and described later) by ultrasonic bonding.

Furthermore, the outer frame 21 houses on the

side of the outer wall 21a nuts opposite openings for the one end portions of the first connection terminals 22a, 22b, and 22c and the second connection terminals 23a, 23b, and 23c. Similarly, the outer frame 21 houses on the side of the outer wall 21c nuts opposite openings for the one end portions of the U-phase output terminal 24c, the V-phase output terminal 24b, and the W-phase output terminal 24a.

In addition, the outer frame 21 has the control terminals 25a, 25b, and 25c in plan view on the front surface along sides in the +Y direction of the unit housing portions 21e1, 21e2, and 21e3, respectively, (on the side of the outer wall 21c). The control terminals 25a may be divided into two groups. The control terminals 25b may be divided into two groups. The control terminals 25c may be divided into two groups. One end portions of the control terminals 25a, 25b, and 25c extend vertically upward (in the +Z direction) from the front surfaces on the side of the outer wall 21c of the unit housing portions 21e1, 21e2, and 21e3, respectively. The other end portions of the control terminals 25a, 25b, and 25c are exposed in the-Y direction in the unit housing portions 21e1, 21e2, and 21e3 from the side of the outer wall 21c of the unit housing portions 21e1, 21e2, and 21e3, respectively.

The above outer frame 21 includes the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c and is integrally molded therewith by injection molding by the use of a thermoplastic resin. By doing so, the case 20 is formed. The thermoplastic resin is polyphenylene sulfide resin, polybutylene terephthalate resin, polybutylene succinate resin, polyamide resin, acrylonitrile butadiene styrene resin, or the like.

Furthermore, the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c are made of metal having good electrical conductivity. Such metal may be copper, aluminum, an alloy containing at least one of them as a main component, or the like. Plating treatment may be performed on the surfaces of the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c. At this time, nickel, a nickel-phosphorus alloy, a nickel-boron alloy, or the like is used as a plating material.

The unit housing portions 21e1, 21e2, and 21e3 of the outer frame 21 are filled with the sealing member to seal the semiconductor units 10 in the unit housing portions 21e1, 21e2, and 21e3. At this time, the other end portions of the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c in the unit housing portions 21e1, 21e2, and 21e3 are sealed with the sealing member. In addition, wires 26 described later are also sealed with the sealing member. The sealing member may be a thermosetting resin such as epoxy resin, phenolic resin, maleimide resin, or polyester resin. Moreover, the sealing member may be gel. Furthermore, a filler may be added to the sealing member. The filler is ceramics having an insulating property and high thermal conductivity.

The heat dissipation plate 3 is rectangular in plan view and has the shape of a flat plate. The heat dissipation plate 3 may correspond in plan view to the outer frame 21 in shape. Each corner portion of the heat dissipation plate 3 may be R-chamfered in plan view.

Furthermore, insertion holes corresponding to the fastening holes 21i are made in plan view in the heat dissipation plate 3. The back surfaces of the semiconductor units 10a, 10b, and 10c are located on the front surface of the heat dissipation plate 3 with a bonding member described later therebetween. In addition, the back surface of the case 20 (outer frame 21) is located on the front surface of the heat dissipation plate 3 with an adhesive described later therebetween. As a result, the semiconductor units 10a, 10b, and 10c are housed in the case 20 on the front surface of the heat dissipation plate 3. Moreover, wiring is performed on the semiconductor units 10a, 10b, and 10c and the unit housing portions 21e1, 21e2, and 21e3 are sealed with the sealing member. By doing so, the semiconductor device 1 in which the semiconductor module 2 is formed on the heat dissipation plate 3 is obtained. A cooler may be formed in an area corresponding to a disposition area of the semiconductor module 2 on the back surface of the heat dissipation plate 3. A refrigerant circulates through the cooler and cooling is performed. Alternatively, a plurality of heat dissipation fins may be formed on the back surface of the heat dissipation plate 3.

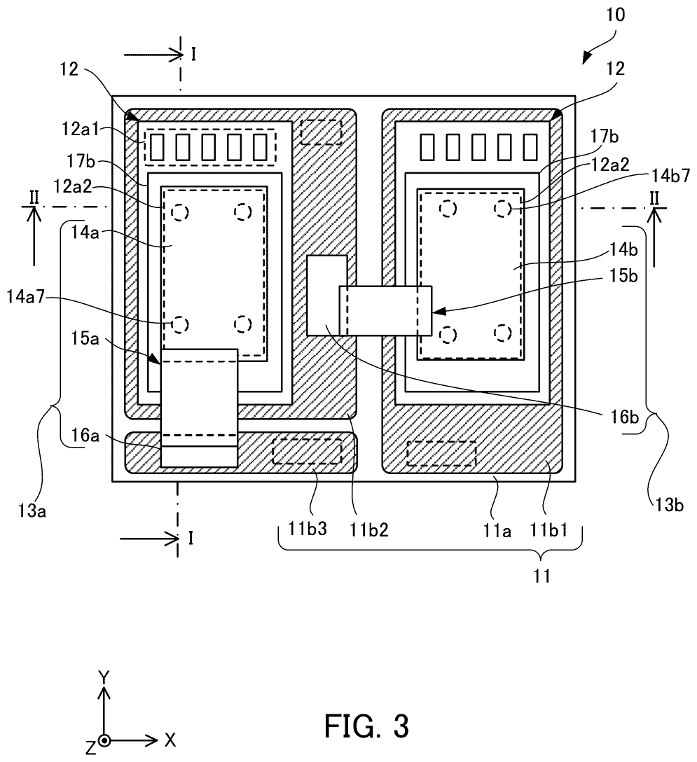

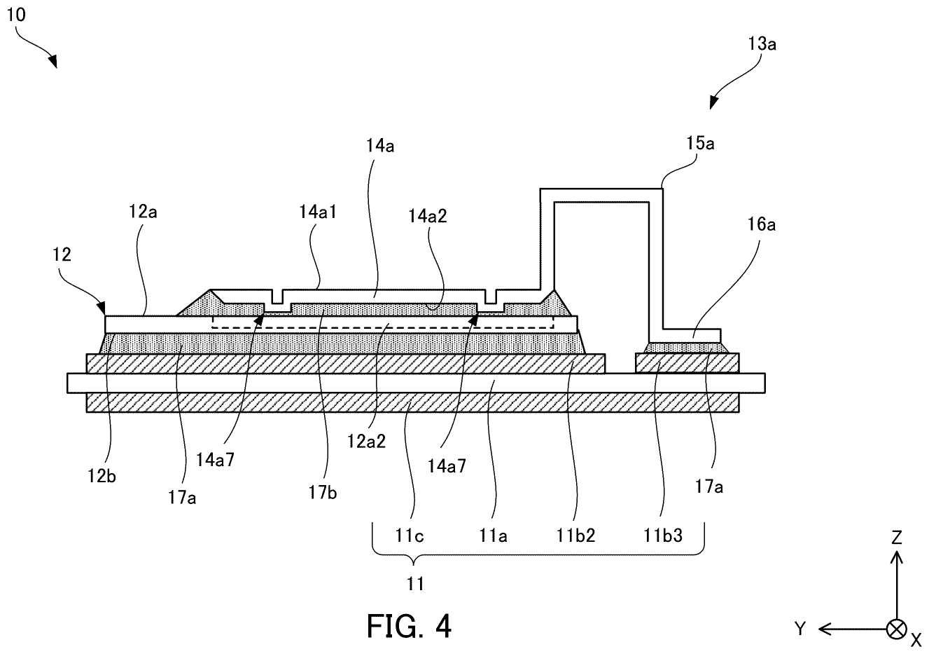

The semiconductor units 10a, 10b, and 10c (semiconductor units 10) will now be described with reference to FIG. 3 and FIG. 4. FIG. 3 is a plan view of a semiconductor unit included in the semiconductor device according to the first embodiment. FIG. 4 is a side sectional view of the semiconductor unit included in the semiconductor device according to the first embodiment. FIG. 4 is a sectional view taken along the dot-dash line I-I of

FIG. 3. Furthermore, in FIG. 3, the positions of main electrodes 12a2 and bosses 14a7 and 14b7 relative to main electrode bonding portions 14a and 14b described later are indicated by dashed lines.

A semiconductor unit 10 may be an inverter circuit corresponding to one phase. The semiconductor unit 10 includes an insulated circuit board 11, two semiconductor chips 12, and lead frames 13a and 13b. The semiconductor chips 12 are bonded to the insulated circuit board 11 with solder 17a.

The insulated circuit board 11 includes an insulating plate 11a, conductive circuit patterns 11b1, 11b2, and 11b3, and a metal plate 11c. The insulating plate 11a and the metal plate 11c are rectangular in plan view. Furthermore, corner portions of the insulating plate 11a and the metal plate 11c may be R-chamfered or C-chamfered. The size of the metal plate 11c is smaller in plan view than that of the insulating plate 11a and the metal plate 11c is formed inside the insulating plate 11a.

The insulating plate 11a has an insulating property and is made of a material, such as ceramics, having high thermal conductivity. The ceramics are aluminum oxide, aluminum nitride, silicon nitride, or the like.

Each of the conductive circuit patterns 11b1, 11b2, and 11b3 is an example of a conductive plate and the conductive circuit patterns 11b1, 11b2, and 11b3 are formed on the front surface of the insulating plate 11a. The conductive circuit patterns 11b1, 11b2, and 11b3 are made of metal having good electrical conductivity. Such metal is copper, aluminum, an alloy containing at least one of them as a main component, or the like. In order to improve corrosion resistance, plating treatment may be performed on the surfaces of the conductive circuit patterns 11b1, 11b2, and 11b3. At this time, nickel, a nickel-phosphorus alloy, a nickel-boron alloy, or the like is used as a plating material.

The conductive circuit pattern 11b1 occupies an area corresponding to the +X side half of the front surface of the insulating plate 11a and extending from the side in the −Y direction to the side in the +Y direction. The other end portions of the first connection terminals 22a, 22b, and 22c are bonded to an area in the conductive circuit pattern 11b1 enclosed by a dashed line. At this time, the ultrasonic bonding or the like may be used.

The conductive circuit pattern 11b2 occupies an area corresponding to −X side half of the front surface of the insulating plate 11a. Furthermore, the area occupied by the conductive circuit pattern 11b2 extends from the side in the +Y direction of the front surface of the insulating plate 11a to a position near the side in the −Y direction of the front surface of the insulating plate 11a. The other end portions of the W-phase output terminal 24a, the V-phase output terminal 24b, and the U-phase output terminal 24c are bonded to an area in the conductive circuit pattern 11b2 enclosed by a dashed line. At this time, the ultrasonic bonding or the like may be used.

The conductive circuit pattern 11b3 occupies an area on the front surface of the insulating plate 11a enclosed by the conductive circuit patterns 11b1 and 11b2. The other end portions of the second connection terminals 23a, 23b, and 23c are bonded to an area in the conductive circuit pattern 11b3 enclosed by a dashed line. At this time, the ultrasonic bonding or the like may be used.

The conductive circuit patterns 11b1, 11b2, and 11b3 are taken as an example. The number, shape, size, or position of conductive circuit patterns may be properly selected at need.

The metal plate 11c is formed on the back surface of the insulating plate 11a. The metal plate 11c is rectangular. The area of the metal plate 11c is smaller in plan view than that of the insulating plate 11a and is larger in plan view than the sum of the areas in which the conductive circuit patterns 11b1, 11b2, and 11b3 are formed. The corner portions of the metal plate 11c may be R-chamfered or C-chamfered. The metal plate 11c is formed on the entire back surface except for an edge portion of the insulating plate 11a. The metal plate 11c contains, as a main component, metal having high thermal conductivity. Such metal is copper, aluminum, an alloy containing at least one of them, or the like.

A direct copper bonding (DCB) substrate, an active metal brazed (AMB) substrate, or the like may be used as the insulated circuit board 11 having the above structure. The insulated circuit board 11 may be fixed to the front surface of the heat dissipation plate 3 with a bonding member (not illustrated) therebetween. Heat generated by the semiconductor chips 12 is conducted to the heat dissipation plate 3 via the conductive circuit patterns 11b1 and 11b2, the insulating plate 11a, and the metal plate 11c. By doing so, the heat is dissipated.

Lead-free solder is used as the solder 17a and 17b. The lead-free solder contains, as a main component, an alloy containing at least two of tin, silver, copper, zinc, antimony, indium, bismuth, and the like. Furthermore, the solder may contain an additive. In addition, the solder 17a and 17b may contain a minute amount of impurities. This is inevitable. In particular, it is preferable to use Sn(tin)-0.7 Cu (copper) or Sn-5Sb (antimony) as the solder 17b used for bonding the lead frames 13a and 13b described later and the semiconductor chips 12. Sn-5Sb is preferably used. The additive is nickel, germanium, cobalt, silicon, or the like. The solder 17a and 17b containing the additive improves wettability, gloss, and bonding strength and reliability is improved.

In addition, a brazing filler metal or a thermal interface material may be used as a bonding member (not illustrated) for bonding the semiconductor units 10 and the heat dissipation plate 3 together. The brazing filler metal contains, as a main component, at least one of a tin alloy, an aluminum alloy, a titanium alloy, a magnesium alloy, a zirconium alloy, a silicon alloy, and the like. The thermal interface material is an adhesive containing an elastomer sheet, room temperature vulcanization (RTV) rubber, gel, a phase change material, or the like, silicone mixed with ceramics, or the like. By fixing the semiconductor units 10 to the heat dissipation plate 3 with the brazing filler metal or the thermal interface material therebetween, the heat dissipation property of the semiconductor units 10 is improved.

Each semiconductor chip 12 has an upper surface 12a and a lower surface 12b and includes a power device element made of silicon. The power device element is a reverse conducting (RC)—insulated gate bipolar transistor (IGBT). The RC-IGBT is a semiconductor element including an IGBT which is a switching element and a free wheeling diode (FWD) which is a diode element. The IGBT and the FWD are connected in inverse parallel and are formed in one chip.

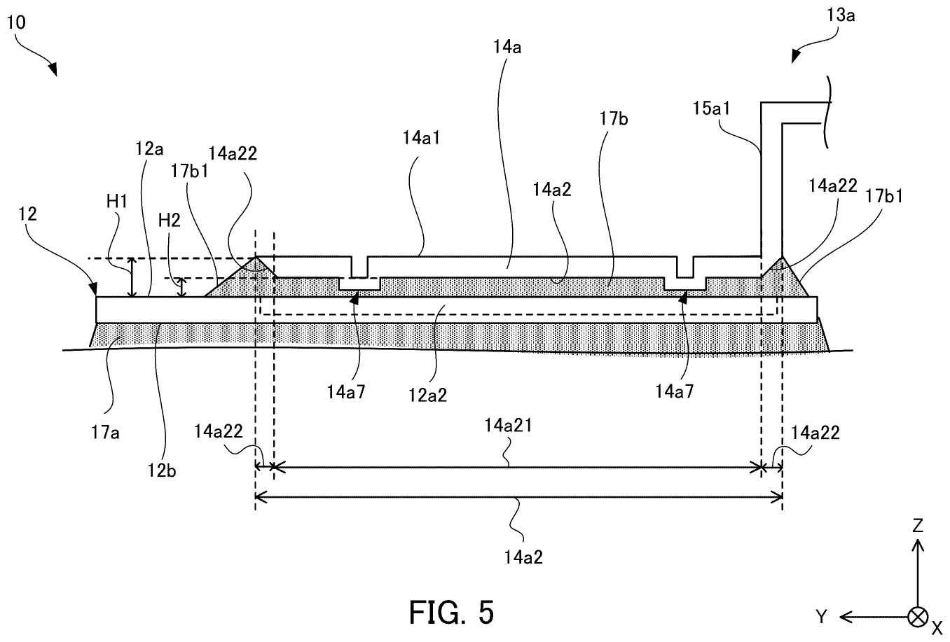

Each semiconductor chip 12 has on the upper surface 12a a control electrode 12a1 (gate electrode) and an output electrode (emitter electrode), which is a main electrode 12a2 (first electrode) (see FIG. 5). Each semiconductor chip 12 has on the lower surface 12b an input electrode (collector electrode), which is a main electrode (second electrode) (not illustrated). The control electrode 12a1 is located on one side of the upper surface 12a of each semiconductor chip 12. The main electrode 12a2 is located in an area of the upper surface 12a except for the control electrode 12a1 of each semiconductor chip 12.

Furthermore, each semiconductor chip 12 may be a power metal-oxide-semiconductor field-effect transistor (MOSFET) made of silicon carbide. With a power MOSFET, a body diode may function as an FWD. In this case, for example, each semiconductor chip 12 has on the back surface an input electrode (drain electrode), which is a main electrode, and has on the front surface an output electrode (source electrode), which is the main electrode 12a2, and the control electrode 12a1 (gate electrode).

In addition, a switching element and a diode element which are made of silicon may be used as each semiconductor chip 12 in place of an RC-IGBT or a power MOSFET. The switching element is an IGBT, a power MOSFET, or the like. In this case, for example, each semiconductor chip 12 has on the lower surface an input electrode (drain electrode or a collector electrode) as a main electrode and has on the upper surface the control electrode 12a1 (gate electrode) and an output electrode (source electrode or an emitter electrode), which is the main electrode 12a2. The diode element may be, for example, a Schottky barrier diode (SBD) or a P-intrinsic-N (PiN) diode, which is used as an FWD. In this case, each semiconductor chip 12 has on the lower surface an output electrode (cathode electrode) as a main electrode and has on the upper surface input electrode (anode electrode) as a main electrode.

The lead frame 13a or 13b is an example of a wiring member. The lead frames 13a and 13b electrically connect the semiconductor chips 12 (over the conductive circuit patterns 11b2 and 11b1) and the conductive circuit patterns 11b1, 11b2, and 11b3.

The lead frame 13a directly connects the main electrode 12a2 of the semiconductor chip 12 (over the conductive circuit pattern 11b2) and the conductive circuit pattern 11b3. The lead frame 13b directly connects the main electrode 12a2 of the semiconductor chip 12 (over the conductive circuit pattern 11b1) and the conductive circuit pattern 11b2. The lead frames 13a and 13b include main electrode bonding portions 14a and 14b (bonding portion), conduction portions 15a and 15b, and circuit bonding portions 16a and 16b, respectively.

The main electrode bonding portions 14a and 14b are bonded to the main electrodes 12a2 of the semiconductor chips 12 (over the conductive circuit patterns 11b2 and 11b1) with the solder 17b therebetween. Only a sectional view of the main electrode bonding portion 14a is given. However, the structure of the main electrode bonding portion 14b is the same as that of the main electrode bonding portion 14a. The details of the main electrode bonding portions 14a and 14b will be described later.

The conduction portions 15a and 15b electrically and mechanically connect the main electrode bonding portions 14a and 14b and the circuit bonding portions 16a and 16b, respectively. For example, the conduction portions 15a and 15b may extend over spaces between the main electrode bonding portions 14a and 14b and the circuit bonding portions 16a and 16b, respectively. The circuit bonding portions 16a and 16b have the shape of a flat plate and are bonded to the conductive circuit patterns 11b3 and 11b2, respectively, with the solder 17a therebetween. In this case, the ultrasonic bonding may be performed in place of the solder 17a. The conduction portion 15a and the circuit bonding portion 16a may be equal in width. The width of the conduction portion 15b may be smaller than that of the circuit bonding portion 16b.

The lead frames 13a and 13b are made of metal,

such as copper, aluminum, or an alloy containing at least one of them as a main component, having good electrical conductivity. In order to improve corrosion resistance, plating treatment may be performed on the surfaces of the lead frames 13a and 13b. At this time, nickel, a nickel-phosphorus alloy, a nickel-boron alloy, or the like is used as a plating material.

Furthermore, the control electrodes 12a1 of the semiconductor chips 12 of the semiconductor units 10a, 10b, and 10c housed in the unit housing portions 21e1, 21e2, and 21e3 of the case 20 are connected mechanically and electrically to the other end portions of the control terminals 25a, 25b, and 25c, respectively, by wires 26. Each wire 26 contains, as a main component, a material, such as gold, copper, aluminum, or an alloy containing at least one of them, having good electrical conductivity. Each wire 26 is preferably an aluminum alloy containing a very small amount of silicon.

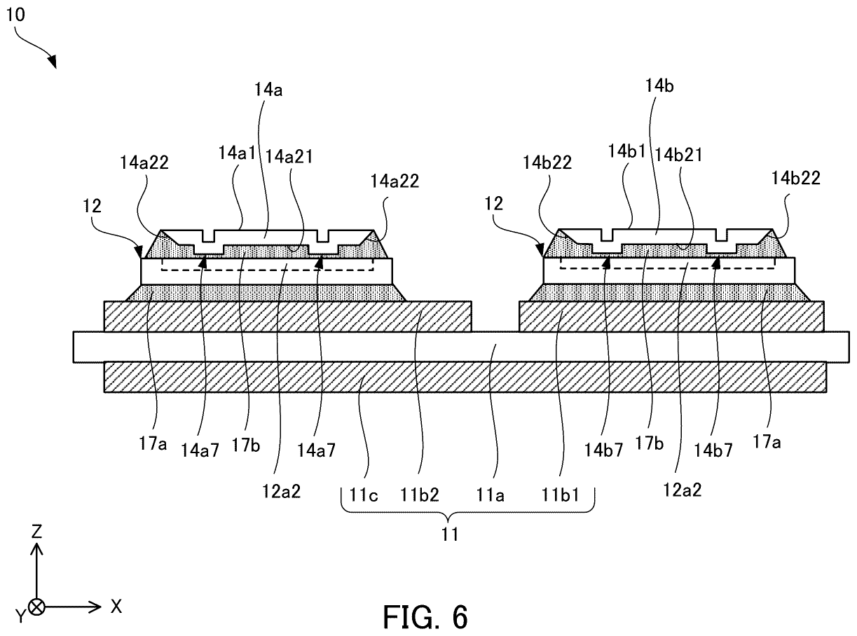

The main electrode bonding portions 14a and 14b of the lead frames 13a and 13b of the semiconductor units 10 will now be described further with reference to FIG. 5 and FIG. 6. FIG. 5 is an enlarged side sectional view of the semiconductor unit included in the semiconductor device according to the first embodiment. FIG. 6 is a side sectional view of the semiconductor unit included in the semiconductor device according to the first embodiment. FIG. 5 illustrates the main electrode bonding portion 14a of the lead frame 13a of FIG. 4 and its surroundings. FIG. 6 is a sectional view taken along the dot-dash line II-II of FIG. 3. FIG. 5 illustrates the main electrode bonding portion 14a of the lead frame 13a. However, the main electrode bonding portion 14b of the lead frame 13b may also have the 10 same structure as the main electrode bonding portion 14a of the lead frame 13a has.

As stated above, the lead frame 13a includes the main electrode bonding portion 14a, the conduction portion 15a, and the circuit bonding portion 16a (not illustrated in FIG. 5). The main electrode bonding portion 14a is rectangular in plan view and has the shape of a flat plate.

The main electrode bonding portion 14a includes an upper surface 14a1 and a bonding surface 14a2. The bonding surface 14a2 is a lower surface of the main electrode 20 bonding portion 14a and is bonded to the main electrode 12a2 of the semiconductor chip 12 with the solder 17b therebetween. Furthermore, bosses 14a7 are formed on the bonding surface 14a2. The upper surface 14a1 and the bonding surface 14a2 are substantially parallel to each other. Concavities 25 corresponding to the bosses 14a7 are formed in the upper surface 14a1. The upper surface 14a1 may be substantially flat except for the concavities.

The area of the bonding surface 14a2 of the main electrode bonding portion 14a is smaller than that of the upper surface 12a of the semiconductor chip 12. Accordingly, in plan view, the bonding surface 14a2 of the main electrode bonding portion 14a is located inside the upper surface 12a of the semiconductor chip 12 (is included in the inside of the upper surface 12a).

Furthermore, a first height H1 from an outer edge area 14a22 of the bonding surface 14a2 of the main electrode bonding portion 14a to the upper surface 12a of the semiconductor chip 12 is greater in a side view than a second height H2 from a middle area 14a21 except for the outer edge area 14a22 of the bonding surface 14a2 to the upper surface 12a of the semiconductor chip 12.

In plan view, the outer edge area 14a22 is an outer peripheral portion of the bonding surface 14a2 which is continuous and circular. The outer edge area 14a22 may have a predetermined width from an outer end portion of the bonding surface 14a2. The width of the whole of the outer edge area 14a22 may be uniform. In the first embodiment, the outer edge area 14a22 is inclined so that the outer edge area 14a22 will separate from the upper surface 12a of the semiconductor chip 12 toward the outside. Specifically, the outer edge area 14a22 is inclined at an obtuse angle to the middle area 14a21. As a result, the first height H1 is the shortest distance from an outer end portion of the outer edge area 14a22 (connecting portion of the outer edge area 14a22 and the upper surface 14a1) to the upper surface 12a of the semiconductor chip 12 just thereunder.

As stated above, the middle area 14a21 is obtained by excluding the outer edge area 14a22 from the bonding surface 14a2. The middle area 14a21 may be approximately parallel to the upper surface 12a of the semiconductor chip 12. The second height H2 is the distance between the middle area 14a21 and the upper surface 12a of the semiconductor chip 12 and the whole of the second height H2 may be uniform.

The bosses 14a7 may be formed in the middle area 14a21 of the bonding surface 14a2. For example, the bosses 14a7 may be formed in the four corners of the middle area 14a21. By forming the bosses 14a7, the thickness of the solder 17b between the bonding surface 14a2 and the upper surface 12a of the semiconductor chip 12 is kept at a predetermined value.

In this case, for example, the height of the bosses 14a7 may be greater than or equal to 0.1 mm and smaller than or equal to 0.4 mm. The height of the bosses 14a7 may be the same. Furthermore, the bosses 14a7 may be cylindrical and the diameter of the bosses 14a7 may be, for example, larger than or equal to 0.5 mm and smaller than or equal to 2.0 mm. The bosses 14a7 may be not cylindrical but prismatic. For example, the bosses 14a7 may be formed by performing press working on the main electrode bonding portion 14a having the shape of a flat plate. As a result, if the bosses 14a7 are formed on the bonding surface 14a2 of the main electrode bonding portion 14a, then portions of the upper surface 14a1 corresponding to the bosses 14a7 are concave. Alternatively, a columnar body or a spherical body may be bonded (for example, by welding) to the bonding surface 14a2. In this case, it is assumed that the main electrode bonding portion 14a has the shape of a flat plate, that the upper surface 14a1 is flat, and that the bonding surface 14a2 is flat.

The conduction portion 15a includes a rising portion 15a1. The rising portion 15a1 rises from the outer periphery of the upper surface 14a1 of the main electrode bonding portion 14a and extends upward. In the first embodiment, the rising portion 15a1 rises almost perpendicularly to the upper surface 14a1 of the main electrode bonding portion 14a. However, the rising portion 15a1 may rise at an obtuse angle to the upper surface 14a1 of the main electrode bonding portion 14a. The rising portion 15a1 is formed, in plan view, in the X direction along the outer periphery in the −Y direction of the main electrode bonding portion 14a.

As stated above, the lead frame 13b also includes the main electrode bonding portion 14b, the conduction portion 15b, and the circuit bonding portion 16b. The main electrode bonding portion 14b includes an upper surface 14b1 and a bonding surface 14b2. The bonding surface 14b2 is a lower surface of the main electrode bonding portion 14b and is bonded to the main electrode 12a2 of the semiconductor chip 12 with the solder 17b therebetween. This is the same as the main electrode bonding portion 14a. Furthermore, bosses 14b7 are formed on the bonding surface 14b2. This is the same as the bonding surface 14a2.

The conduction portion 15b includes a rising portion. This is the same as the conduction portion 15a. The rising portion rises almost perpendicularly to the upper surface 14b1 of the main electrode bonding portion 14b. However, the rising portion may rise at an obtuse angle to the upper surface 14b1 of the main electrode bonding portion 14b. The rising portion is formed, in plan view, in the Y direction along the outer periphery in the −X direction of the main electrode bonding portion 14b (see FIG. 3).

Furthermore, the solder 17b bonds the main electrode bonding portion 14a of the lead frame 13a and the upper surface 12a of the semiconductor chip 12 together. A side part of the outer periphery of the solder 17b which circularly continues has a shape (shape of a fillet) which spreads toward the outside. An outer peripheral side surface 17b1 of the solder 17b having the shape of a fillet connects an end portion of the upper surface 12a (main electrode 12a2) of the semiconductor chip 12 and an end portion of the upper surface 14a1 of the main electrode bonding portion 14a. An angle at which the outer peripheral side surface 17b1 is inclined to the upper surface 12a (main electrode 12a2) of the semiconductor chip 12 may be greater than or equal to 20° and less than or equal to 45°.

In addition, the middle area 14a21, the outer edge area 14a22, and the bosses 14a7 of the main electrode bonding portion 14a are buried in the solder 17b. The upper surface 14a1 may be exposed from the solder 17b. There is a gap between each boss 14a7 and the upper surface 12a of the semiconductor chip 12. The solder 17b is formed in this gap. As a result, the bottom of each boss 14a7 and the upper surface 12a of the semiconductor chip 12 are bonded together.

A first thickness of an outer edge portion of the solder 17b which is in contact with the outer edge area 14a22 of the bonding surface 14a2 is also the first height H1. A second thickness of a central portion of the solder 17b which is in contact with the middle area 14a21 of the bonding surface 14a2 is also the second height H2. At this time, the first thickness (first height H1) is greater than the second thickness (second height H2). For example, the first height H1 may be smaller than or equal to 750 μm. In addition, for example, the second height H2 may be greater than or equal to 150 μm and smaller than or equal to 350 μm.

Because the outer edge area 14a22 is inclined, the solder 17b comes in contact with the outer edge area 14a22. At this time, the shortest distance from the outer end portion of the outer edge area 14a22 (upper surface 14a1) to the upper surface 12a of the semiconductor chip 12 is the first thickness. The first thickness corresponds to the thickest portion of the solder 17b. Specifically, the outer edge portion of the solder 17b includes the thickest portion.

An outer edge portion of the solder 17b which bonds the main electrode bonding portion 14b of the lead frame 13b and the upper surface 12a of the semiconductor chip 12 together includes the thickest portion. This is the same as the above outer edge portion of the solder 17b.

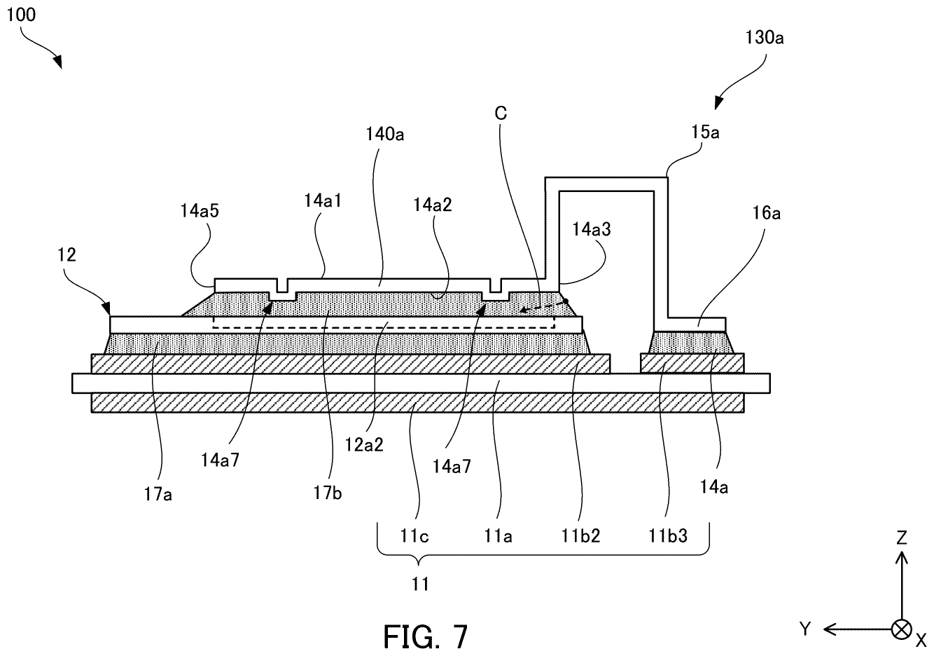

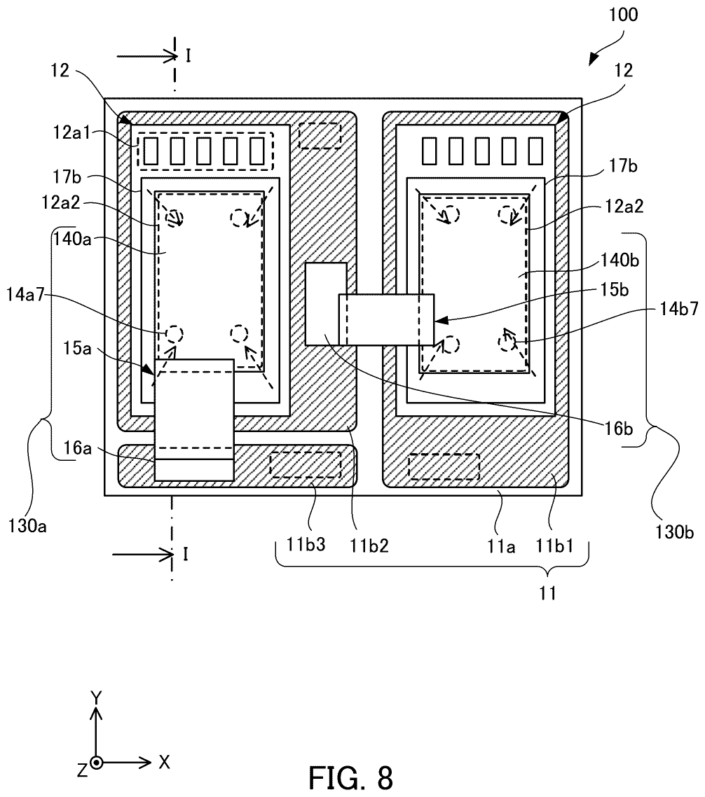

A semiconductor unit 100 included in a semiconductor device taken as reference example 1 will be described with reference to FIG. 7 and FIG. 8. FIG. 7 is a side sectional view of a semiconductor unit included in a semiconductor device taken as reference example 1. FIG. 8 is a plan view of the semiconductor unit included in the semiconductor device taken as reference example 1. FIG. 7 and FIG. 8 correspond to FIG. 4 and FIG. 3, respectively, in the first embodiment. FIG. 7 is a sectional view taken along the dot-dash line I-I of FIG. 8. Furthermore, in FIG. 8, the positions of main electrodes 12a2 and bosses 14a7 and 14b7 relative to main electrode bonding portions 140a and 140b described later are indicated by dashed lines.

With reference example 1, a semiconductor device 1 includes the semiconductor unit 100 in place of the semiconductor unit 10. The semiconductor unit 100 and the semiconductor unit 10 in the first embodiment are equal in structure. However, lead frames 130a and 130b differ from the lead frames 13a and 13b, respectively, in the first embodiment. The lead frames 130a and 130b included in the semiconductor device 1 taken as reference example 1 include main electrode bonding portions 140a and 140b, conduction portions 15a and 15b, and circuit bonding portions 16a and 16b, respectively. This is the same as the lead frames 13a and 13b in the first embodiment. Unlike the main electrode bonding portions 14a and 14b in the first embodiment, however, the main electrode bonding portions 140a and 140b included in the semiconductor device 1 taken as reference example 1 have the shape of a flat plate and the whole of each of the main electrode bonding portions 140a and 140b is uniform in thickness.

Furthermore, with the semiconductor device 1 taken as reference example 1, the thickness of solder 17b which bonds the main electrode bonding portions 140a and 140b of the lead frames 130a and 130b and upper surfaces 12a of semiconductor chips 12 together is greater than the second height H2 in the first embodiment.

With the semiconductor unit 100 included in the semiconductor device 1 taken as reference example 1, in a power cycle, the semiconductor chips 12 and the main electrode bonding portions 140a and 140b of the lead frames 130a and deform due to heat generated by the semiconductor chips 12. As a result, the solder 17b expands and contracts and is distorted. At this time, a crack may appear, in plan view, in an outer end portion of the solder 17b. For example, a crack may appear, in plan view, at some spot on the outer end portion (especially near a short side of the main electrode bonding portion 140a or 140b) of the solder 17b. As illustrated in FIG. 7, when the solder 17b repeatedly expands and contracts as a result of power cycles, a crack C progresses to the inside of the solder 17b. Furthermore, a crack may appear, in plan view, in each corner portion of the outer end portion of the solder 17b. In this case, as illustrated in FIG. 8, the crack progresses, in plan view, from each of the four corners (from each of the corner portions) of the solder 17b to the inside of the solder 17b. When the crack C progresses to the inside of the solder 17b and the solder 17b deteriorates, the heat conduction property of the solder 17b deteriorates. This deteriorates cooling performance on the semiconductor chip 12. As a result, a failure easily occurs in the semiconductor chips 12. The description of the lead frame 130a has given. However, this is the same as the solder 17b of the lead frame 130b. That is to say, a crack C may appear in the solder 17b of the lead frame 130b and progress to the inside of the solder 17b.

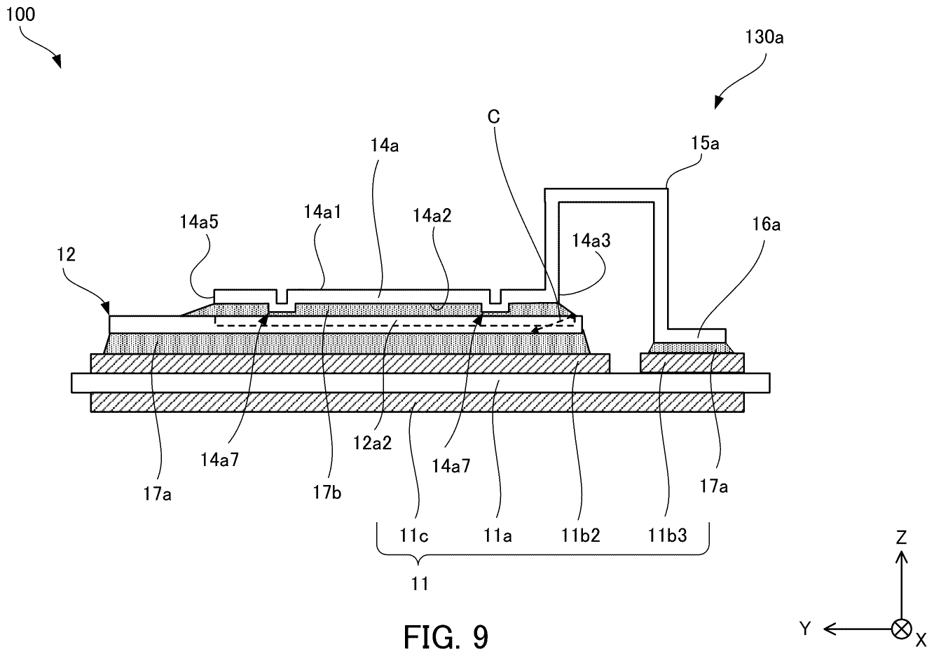

Furthermore, in the case of a semiconductor unit 100 included in a semiconductor device taken as reference example 2, the thickness of the solder 17b in the semiconductor unit 100 included in the semiconductor device 1 taken as reference example 1 is less than the second height H2 in the first embodiment. The semiconductor unit 100 included in the semiconductor device taken as reference example 2 has the same configuration as the semiconductor unit 100 included in the semiconductor device 1 taken as reference example 1 except for the thickness of solder 17b. The semiconductor unit 100 included in the semiconductor device taken as reference example 2 will be described with reference to FIG. 9. FIG. 9 is a side sectional view of the semiconductor unit included in the semiconductor device taken as reference example 2. FIG. 9 corresponds to FIG. 7. Furthermore, FIG. 9 illustrates a lead frame 130a. However, the same applies to a lead frame 130b. That is to say, the lead frame 130b is bonded to a semiconductor chip 12 with the solder 17b having thickness less than the second height H2.

With the semiconductor unit 100 included in the semiconductor device taken as reference example 2, in a power cycle, the solder 17b expands and contracts and is distorted. As a result, a crack tends to appear in plan view in an outer end portion of the solder 17b. In particular, if the solder 17b is thin, a crack tends to appear and a crack C tends to progress. In the case of reference example 2, the heat conduction property of the solder 17b including the crack C deteriorates and cooling performance on the semiconductor chip 12 deteriorates. This is the same as the case of reference example 1.

In addition, if the solder 17b is thin, then the possibility that the crack C will progress and that the crack C will reach a main electrode 12a2 of the semiconductor chip 12 becomes stronger. In this case, as illustrated in FIG. 9, the main electrode 12a2 of the semiconductor chip 12 may suffer damage. From this point of view, a failure occurs in the semiconductor chips 12 more easily.

Furthermore, as the power density and capacity of a semiconductor module 2 (semiconductor unit 100) increase, such deterioration of the solder 17b becomes more noticeable. Accordingly, with the semiconductor unit 100 corresponding to reference example 1 or 2, for example, epoxy resin is used as a sealing member. By doing so, expansion or contraction of the solder 17b is suppressed and the progress of deterioration of the solder 17b caused by a crack C is delayed. However, the use of epoxy resin leads to an increase in the costs.

The above semiconductor device 1 includes the semiconductor chip 12 having the main electrode 12a2 on the upper surface 12a and the other main electrode on the lower surface 12b and the lead frame 13a. The lead frames 13a includes the main electrode bonding portion 14a and the rising portion 15a1. The main electrode bonding portion 14a has the bonding surface 14a2 bonded to the main electrode 12a2 with the solder 17b therebetween. The bonding surface 14a2 is located, in plan view, inside the upper surface 12a of the semiconductor chip 12. The rising portion 15a1 extends from the outer periphery of the main electrode bonding portion 14a. Furthermore, the first height H1 from the outer edge area 14a22 of the bonding surface 14a2 to the upper surface 12a of the semiconductor chip 12 is greater than the second height H2 from the middle area 14a21 except for the outer edge area 14a22 of the bonding surface 14a2 to the upper surface 12a of the semiconductor chip 12. Accordingly, the first thickness (first height H1) of the outer edge portion of the solder 17b which is in contact with the outer edge area 14a22 of the bonding surface 14a2 is also greater than the second thickness (second height H2) of the central portion of the solder 17b which is in contact with the middle area 14a21 of the bonding surface 14a2. That is to say, if the outer edge side of the solder 17b is thicker, in plan view, than the center of the solder 17b, then stress generated in the outer edge side of the solder 17b is reduced. In addition, the bonding surface 14a2 of the main electrode bonding portion 14a keeps at least a certain height from the main electrode 12a2 (upper surface 12a) of the semiconductor chip 12 by the bosses 14a7. Accordingly, even if the semiconductor chips 12 and the main electrode bonding portions 14a and 14b of the lead frames 13a and 13b deform due to heat in a power cycle of the semiconductor device 1, a crack is unlikely to appear in the outer edge of the solder 17b. Even if a crack appears in the outer edge of the solder 17b, the progress of a crack C is suppressed and the progress of deterioration of the solder 17b is delayed. This improves the power cycle resistance of the semiconductor device 1. Moreover, because the progress of deterioration of the solder 17b is delayed, a relatively inexpensive gel may be used as a sealing member in place of epoxy resin. This also reduces the manufacturing costs of the semiconductor device 1.

Furthermore, in order to decrease stress applied

to the solder 17b as a result of a power cycle of the semiconductor device 1, it is desirable that the solder 17b be made of a material having high strength. For example, it is desirable that the solder 17b contain Sn-0.7 Cu or Sn-5Sb. In order to obtain higher power cycle resistance, it is desirable that the Young's modulus at 25° C. be greater than or equal to 50 GPa and that the yield point be smaller than or equal to 30 MPa. For example, the solder 17b which is in this range is Sn-5Sb. High strength and a high heat resistance property are realized by the solder 17b containing Sn-5Sb and the power cycle resistance of the semiconductor device 1 is improved further.

### Modification 1-1

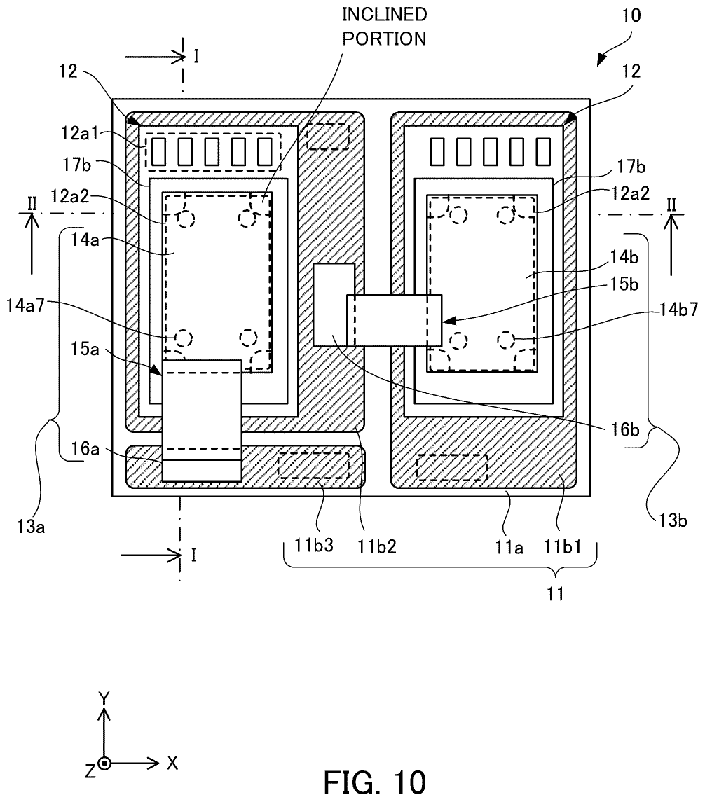

Modification 1-1 of the first embodiment will be described with reference to FIG. 10. FIG. 10 is a plan view of a semiconductor unit included in a semiconductor device according to the first embodiment (modification 1-1). FIG. 10 corresponds to FIG. 3 first embodiment. Furthermore, in FIG. 10, the positions of main electrodes 12a2 and bosses 14a7 and 14b7 relative to main electrode bonding portions 14a and 14b are indicated by dashed lines.

With the semiconductor device 1 according to the first embodiment, the outer edge areas 14a22 and 14b22 of the lead frames 13a and 13b are inclined to the middle areas 14a21 and 14b21, respectively, so that the outer edge side of the solder 17b will be thicker than the center of the solder 17b (see FIG. 5 and FIG. 6). This reduces stress generated in the outer edge of the solder 17b. Furthermore, as described in reference examples 1 and 2, a crack tends to progress, in plan view, from each of the four corners of the outer end portion of the solder 17b to the inside of the solder 17b.

Accordingly, in the semiconductor device 1, as

illustrated in FIG. 10, only at least four corners of the outer edge areas 14a22 and 14b22 of the lead frames 13a and 13b (see FIG. 6) may be inclined in plan view. In this case, even if the semiconductor chips 12 and the main electrode bonding portions 14a and 14b of the lead frames 13a and 13b deform due to heat in a power cycle of the semiconductor device 1, a crack is unlikely to appear in each corner portion of the solder 17b. Even if a crack appears in each corner portion of the solder 17b, the progress of a crack C is suppressed and the progress of deterioration of the solder 17b is delayed.

In addition, in the semiconductor device 1, the outer edge areas 14a22 and 14b22 of the lead frames 13a and 13b may be inclined not only in the four corners but also in portions corresponding to parts of the outer end portion of the solder 17b in which a crack tends to appear and in which the crack tends to progress.

### Modification 1-2

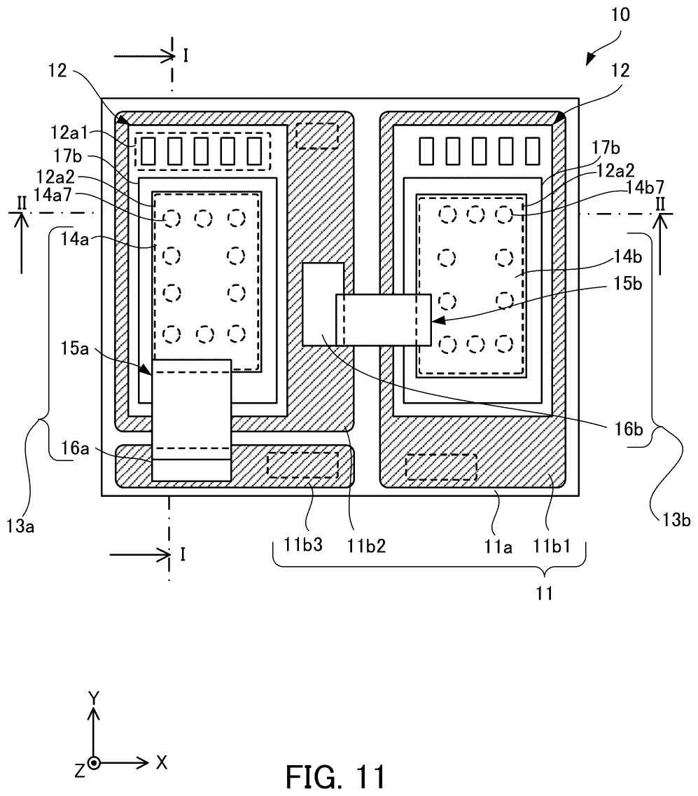

Modification 1-2 of the first embodiment will be described with reference to FIG. 11. FIG. 11 is a plan view of a semiconductor unit included in a semiconductor device according to the first embodiment (modification 1-2). FIG. 11 corresponds to FIG. 3 in the first embodiment. Furthermore, in FIG. 11, the positions of main electrodes 12a2 and bosses 14a7 and 14b7 relative to main electrode bonding portions 14a and 14b are indicated by dashed lines. In addition, FIG. 4 through FIG. 6 may be referred to for lead frames 13a and 13b in modification 1-2.

In the semiconductor device 1 according to the first embodiment, the bosses 14a7 are formed in the four corners of the middle area 14a21 of the bonding surface 14a2 of the lead frame 13a (see FIG. 3 through FIG. 6). Similarly, the bosses 14b7 are formed in the four corners of the middle area 14b21 of the bonding surface 14b2 of the lead frame 13b (see FIG. 3 through FIG. 6).

Such bosses 14a7 are formed in the four corners of a middle area 14a21. In addition, five or more bosses 14a7 may be formed along the outer periphery of the middle area 14a21. As illustrated in FIG. 11, for example, ten bosses 14a7 may be formed along the outer periphery of the middle area 14a21 of the bonding surface 14a2. As the number of the bosses 14a7 increases, a first height H1 and a second height H2 of solder 17b are maintained more reliably. As a result, even if semiconductor chips 12 and the main electrode bonding portions 14a and 14b of the lead frames 13a and 13b deform due to heat in a power cycle of a semiconductor device 1, a crack is more unlikely to appear in each corner portion of the solder 17b. Even if a crack appears in each corner portion of the solder 17b, the progress of a crack C is suppressed and the progress of deterioration of the solder 17b is delayed further.

### Second Embodiment

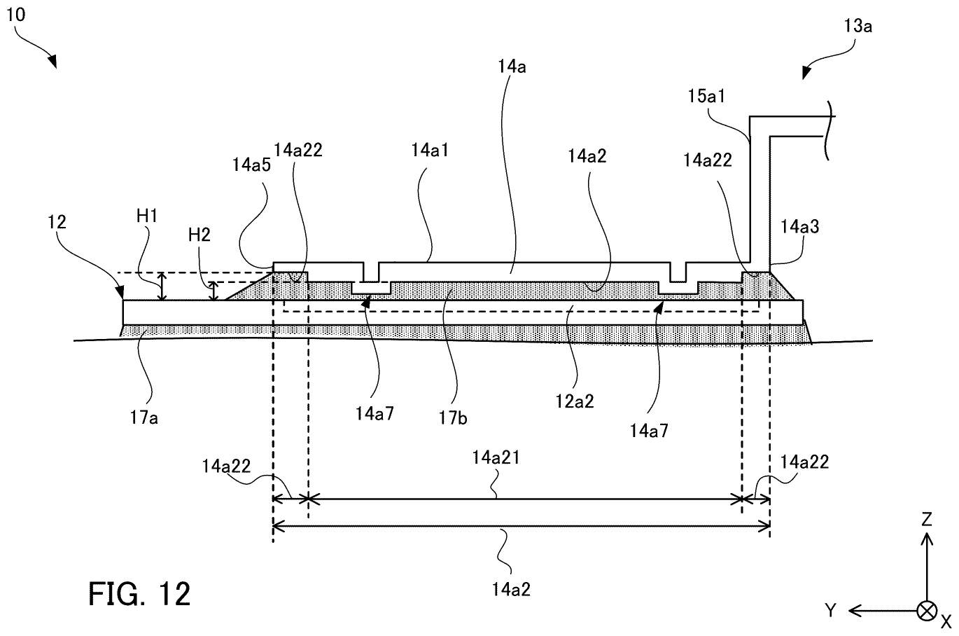

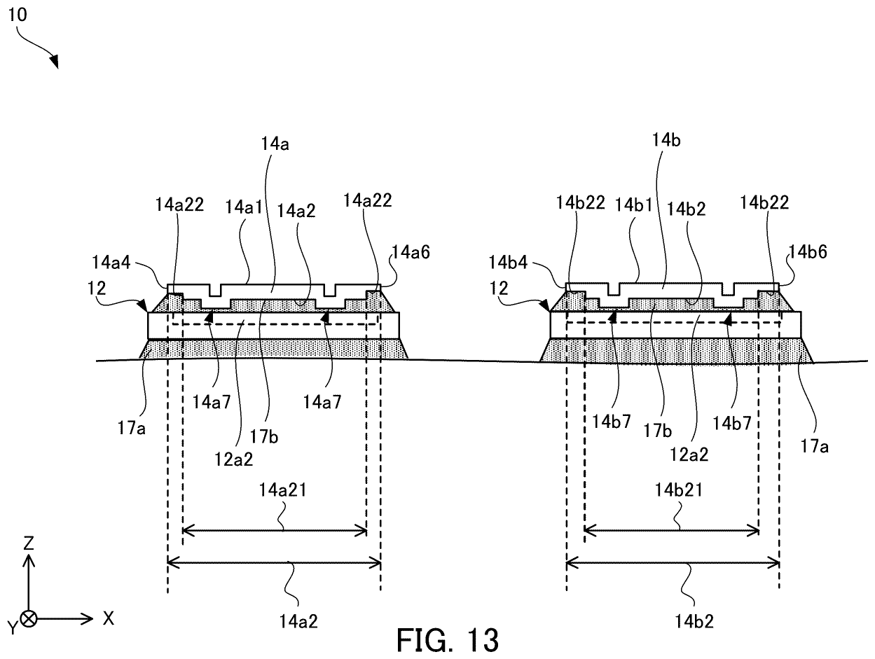

Outer edge areas 14a22 and 14b22 of main electrode bonding portions 14a and 14b of lead frames 13a and 13b in the second embodiment differ from the outer edge areas 14a22 and 14b22 of the main electrode bonding portions 14a and 14b of the lead frames 13a and 13b, respectively, in the first embodiment. Such a semiconductor device will be described with reference to FIG. 12 and FIG. 13. FIG. 12 is an enlarged side sectional view of a semiconductor unit included in a semiconductor device according to the second embodiment. FIG. 13 is a side sectional view of the semiconductor unit included in the semiconductor device according to the second embodiment. The semiconductor device according to the second embodiment has the same configuration as the semiconductor device 1 according to the first embodiment except for the outer edge areas 14a22 and 14b22 of the lead frames 13a and 13b. FIG. 3 may be referred to for a plan view of a semiconductor unit 10 in the second embodiment. FIG. 12 is an enlarged view of a section obtained along the dot-dash line I-I of FIG. 3. FIG. 13 illustrates a section obtained along the dot-dash line II-II of FIG. 3. An insulated circuit board 11 is not illustrated in FIG. 12 or FIG. 13.

The outer edge areas 14a22 and 14b22 of bonding surfaces 14a2 and 14b2 of the main electrode bonding portions 14a and 14b included in the lead frames 13a and 13b in the second embodiment form level differences with respect to middle areas 14a21 and 14b21 of the bonding surfaces 14a2 and 14b2, respectively, and are located above (+Z direction) the middle areas 14a21 and 14b21, respectively. The outer edge areas 14a22 and 14b22 are approximately parallel to upper surfaces 14a1 and 14b1 of the main electrode bonding portions 14a and 14b, respectively, and are flat. Furthermore, for example, the width of the outer edge areas 14a22 and 14b22 (inward distance in plan view from outer edge portions of the main electrode bonding portions 14a and 14b) may be longer than or equal to 0.5 mm and shorter than or equal to 3 mm.

Accordingly, a first height H1 from the outer edge areas 14a22 and 14b22 of the bonding surfaces 14a2 and 14b2 of the lead frames 13a and 13b to upper surfaces 12a of semiconductor chips 12 is greater than a second height H2 from the middle areas 14a21 and 14b21 of the bonding surfaces 14a2 and 14b2 to the upper surfaces 12a of the semiconductors chip 12. As a result, in the second embodiment, a first thickness (first height H1) of outer edge portions of solder 17b which are in contact with the outer edge areas 14a22 and 14b22 of the bonding surfaces 14a2 and 14b2 is also greater than a second thickness (second height H2) of central portions of the solder 17b which are in contact with the middle areas 14a21 and 14b21 of the bonding surfaces 14a2 and 14b2. In FIG. 12, the first height H1 and the second height H2 with the lead frame 13a are indicated. However, the same heights H1 and H2 apply to the lead frame 13b. That is to say, outer edges of the solder 17b are thicker, in plan view, than the central portions of the solder 17b. This decreases stress generated in the outer edges of the solder 17b. As a result, the power cycle resistance of the semiconductor device 1 is improved. This is the same as the first embodiment.

In the second embodiment, only at least four corners of the outer edge areas 14a22 and 14b22 of the lead frames 13a and 13b may form level differences, in plan view, with respect to the middle areas 14a21 and 14b21, respectively, and be located above (+Z direction) the middle areas 14a21 and 14b21, respectively. This is the same as modification 1-1 of the first embodiment. Furthermore, in addition to the formation of bosses 14a7 in the four corners of the middle areas 14a21 and 14b21, five or more bosses 14a7 may be formed along the outer periphery of each of the middle areas 14a21 and 14b21. This is the same as modification 1-2 of the first embodiment.

### Third Embodiment

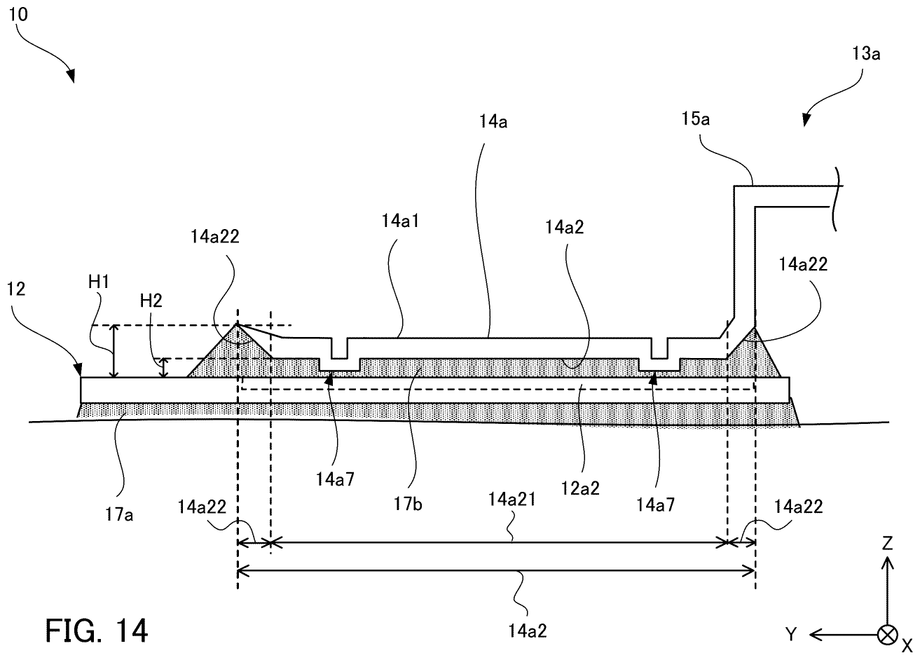

Outer edge areas 14a22 and 14b22 of main electrode bonding portions 14a and 14b of lead frames 13a and 13b in a third embodiment differ from the outer edge areas 14a22 and 14b22 of the main electrode bonding portions 14a and 14b of the lead frames 13a and 13b, respectively, in the first or second embodiment. Such a semiconductor device will be described with reference to FIG. 14. FIG. 14 is an enlarged side sectional view of a semiconductor unit included in a semiconductor device according to a third embodiment. The semiconductor device according to the third embodiment has the same configuration as the semiconductor device 1 according to the first embodiment except for the outer edge areas 14a22 and 14b22 of the lead frames 13a and 13b. FIG. 14 is an enlarged view of the section obtained along the dot-dash line I-I of FIG. 3. The section obtained along the dot-dash line II-II of FIG. 3 is not illustrated. Furthermore, the main electrode bonding portion 14a of the lead frame 13a will now be described. However, the same applies to the main electrode bonding portion 14b of the lead frame 13b.

The outer edge area 14a22 of a bonding surface 14a2 of the main electrode bonding portion 14a is inclined so that the outer edge area 14a22 will separate from an upper surface 12a of a semiconductor chip 12 toward the outside. Furthermore, the outer edge area 14a22 is inclined and extends so that an outer end portion of the outer edge area 14a22 will be located above an upper surface 14a1 opposite to the bonding surface 14a2 of the main electrode bonding portion 14a. Accordingly, a first height H1 from the outer edge area 14a22 of the bonding surface 14a2 of the lead frame 13a to the upper surface 12a of the semiconductor chip 12 is greater than the first height H1 in the first embodiment. A second height H2 may be equal to the second height H2 in the first embodiment.

As a result, a first thickness (first height H1) of an outer edge portion of solder 17b which is in contact with the outer edge area 14a22 of the bonding surface 14a2 is greater than the first thickness (first height H1) in the first embodiment. Accordingly, stress generated in the outer edge side of the solder 17b in the third embodiment is decreased compared with the first embodiment. As a result, the power cycle resistance of the semiconductor device is improved compared with the first embodiment.

According to the disclosed techniques, the progress of deterioration of solder is delayed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip including a first electrode on an upper surface thereof and a second electrode on a lower surface thereof; and
a wiring member including
a bonding portion having a bonding surface, which is bonded to the first electrode with a solder therebetween, and
a rising portion extending from an outer periphery of the bonding portion,
the bonding surface being located, in a plan view of the semiconductor device, within the upper surface of the semiconductor chip, wherein
the bonding surface has an outer edge area and a middle area different from the outer edge area, and
in a height direction of the semiconductor device, a first height from the outer edge area of the bonding surface to the upper surface of the semiconductor chip is greater than a second height from the middle area of the bonding surface to the upper surface of the semiconductor chip.

2. The semiconductor device according to claim 1, wherein
the solder has
an outer edge portion that is in contact with the outer edge area of the bonding surface, and
a central portion that is in contact with the middle area of the bonding surface,
a thickness of the outer edge portion of the solder being greater than that of the central portion.

3. The semiconductor device according to claim 2, wherein:
the thickness of the outer edge portion of the solder is less than or equal to 750 μm; and
the thickness of the central portion of the solder is greater than or equal to 150 μm and less than or equal to 350 μm.

4. The semiconductor device according to claim 2, wherein
the solder has an outer peripheral side surface that is in contact with the semiconductor chip, and
the outer peripheral side surface forms a tilt angle that is greater than or equal to 20° and less than or equal to 45° with the first electrode of the semiconductor chip.

5. The semiconductor device according to claim 1, wherein the middle area of the bonding surface has a first plurality of bosses formed in four corners thereof.

6. The semiconductor device according to claim 5, wherein a height of each of the first plurality of bosses is greater than or equal to 0.1 mm and smaller than or equal to 0.4 mm.

7. The semiconductor device according to claim 5, wherein the middle area of the bonding surface further has a second plurality of bosses formed along an outer periphery of the middle area of the bonding surface.

8. The semiconductor device according to claim 1, wherein the solder is formed of Sn(tin)-0.7 Cu (copper).

9. The semiconductor device according to claim 1, wherein the solder has
a Young modulus thereof greater than or equal to 50 GPa at 25° C., and
a yield point thereof smaller than or equal to 30 MPa.

10. The semiconductor device according to claim 9, wherein the solder is formed of Sn(tin)-5Sb (antimony).

11. The semiconductor device according to claim 1, wherein the outer edge area of the bonding surface of the bonding portion is in four corners of the bonding surface.

12. The semiconductor device according to claim 1, wherein the outer edge area of the bonding surface of the bonding portion is inclined so that the outer edge area separates from the upper surface of the semiconductor chip toward an outside of the semiconductor device.

13. The semiconductor device according to claim 12, wherein the outer edge area of the bonding surface of the bonding portion is inclined, and extends to have an end portion thereof located above a principal plane opposite to the bonding surface of the bonding portion.

14. The semiconductor device according to claim 1, wherein the outer edge area of the bonding surface of the bonding portion forms a level difference with the middle area of the bonding surface and is located above the middle area.

15. The semiconductor device according to claim 14, wherein a width of the outer edge area is longer than or equal to 0.5 mm and shorter than or equal to 3 mm.

16. The semiconductor device according to claim 1, further comprising a gel sealing the semiconductor chip, the solder, and the wiring member.
